(19) United States
(12) Patent Application Publication
(10) Pub. No.: US 2022/0159836 A1
(43) Pub. Date: May 19, 2022

(54) PCB AND CABLE ASSEMBLY FOR BALANCED HIGH FREQUENCY CONNECTORS

(71) Applicant: 3M INNOVATIVE PROPERTIES COMPANY, St. Paul, MN (US)

(72) Inventors: Steven A. Neu, Cedar Park, TX (US); Dennis L. Doye, Cedar Park, TX (US)

(21) Appl. No.: 17/436,233

(22) PCT Filed: Mar. 25, 2020
(86) PCT No.: PCT/IB2020/052821

§ 371 Date: Sep. 3, 2021

Related U.S. Application Data
(60) Provisional application No. 62/826,277, filed on Mar. 29, 2019.

(51) Int. Cl. H05K 1/11; H01R 12/62; H01R 12/53

(52) U.S. Cl. CPC H05K 1/117; H05K 2201/09145; H01R 12/53; H01R 12/62

(57) ABSTRACT

A connector assembly includes a housing, a circuit board, and a plurality of cables, each including a plurality of conductors. The circuit board is disposed in a cavity of the housing and includes an upper major surface, an opposing lower major surface, a front edge, and a rear edge opposite the front edge. The circuit board includes conductive front pads disposed on the upper and lower major surfaces proximate the front edge, and conductive rear pads disposed on the upper and lower major surfaces proximate the rear edge and electrically connected to the front pads. The rear pads form first and second rows of rear pads on each of the upper and lower major surfaces, with the first row disposed proximate the rear edge and the second row disposed between the first row and the front pads. The plurality of conductors are terminated at the first and second rows of the rear pads on the upper and lower major surfaces.

### SUMMARY

In some aspects of the present description, a connector assembly is provided, including a housing, a circuit board, and a plurality of cables, each including a plurality of conductors. The housing includes top and bottom housing portions assembled to each other and defining a housing cavity therebetween. The housing includes a mating end for mating with a mating connector and an opposing cable end for receiving one or more cables.

The circuit board is disposed in the housing cavity and includes an upper major surface, an opposing lower major surface, a front edge proximate the mating end, and a rear edge opposite the front edge and proximate the cable end. The circuit board includes a plurality of conductive front pads disposed on the upper and lower major surfaces proximate the front edge, and a plurality of conductive rear pads disposed on the upper and lower major surfaces proximate the rear edge and electrically connected to the front pads. The rear pads form first and second rows of rear pads on each of the upper and lower major surfaces, with the first row disposed proximate the rear edge and the second row disposed between the first row and the front pads.

The plurality of conductors of the plurality of cables include uninsulated front ends terminated at the rear pads of the first and second rows of the rear pads on the upper and lower major surfaces. For one of the first rows, at least a portion of each uninsulated front end is disposed between upper and lower planes defined by the respective upper and lower major surfaces.

In some aspects of the present description, a connector assembly is provided, including a housing, a circuit board, and a cable. The circuit board is at least partially disposed inside the housing and includes a plurality of conductive pads disposed on a first major surface thereof, opposite a second major surface. The cable includes a plurality of conductors. The uninsulated front ends of the conductors are terminated at the conductive pads, such that at least a portion of each uninsulated front end is disposed between first and second planes defined by the first and second major surfaces.

In some aspects of the present description, a circuit board assembly is provided, including a circuit board including opposing first and second major surfaces. Uninsulated portions of first and second insulated conductors are terminated at conductive pads disposed on the respective first and second major surfaces, such that, in a side plan view, the uninsulated portion of only one of the first and second conductors extends beyond an edge of the circuit board.

### BRIEF DESCRIPTION OF THE DRAWINGS

FIGS. 1A and 1B are perspective views of a connector assembly, in accordance with an embodiment of the present description;

FIG. 2 is a perspective, cutaway view of a connector assembly, in accordance with an embodiment of the present description;

FIGS. 3A and 3B are perspective views of a printed circuit board for a connector assembly, in accordance with an embodiment of the present description;

FIGS. 4A and 4B are exploded views of a connector assembly, in accordance with an embodiment of the present description;

FIGS. 5A and 5B are perspective views of cables terminating on a printed circuit board in a connector assembly, in accordance with an embodiment of the present description; and

FIG. 6 provides a side view of the cable terminations for a connector assembly, in accordance with an embodiment of the present description.

### DETAILED DESCRIPTION

In the following description, reference is made to the accompanying drawings that form a part hereof and in which various embodiments are shown by way of illustration. The drawings are not necessarily to scale. It is to be understood that other embodiments are contemplated and may be made without departing from the scope or spirit of the present description. The following detailed description, therefore, is not to be taken in a limiting sense.

For high speed cable assemblies, low input differential insertion loss (represented by differential scattering parameter, SDD21) in a connector assembly is a critical factor to minimize error as a signal propagates through the assembly. Multiple components contribute to insertion loss, including the interface with the mating connector, the structure of circuit traces, vias, and pads on the PCB, the quality of the solder connections, the size of the conductors inside the cable, the impedance design of the components, and several other factors.

Of these factors, the PCB can contribute significantly to the total loss of the assembly and mated connectors. For example, a PCB can contribute 6 decibels (dB) or more of loss to a 17.5 dB total assembly. This loss can be minimized with good PCB design practices, such as using PCB materials with lower dielectric constants, and shortening the lengths of circuit traces on the PCB. Shortening the trace lengths on a PCB can reduce insertion loss significantly.

Standard form factors for high-speed cable connector assemblies (such as the Octal Small Form Factor Pluggable Module, OSFP, or the Quad Small Form Factor Pluggable Double Density, QSFP-DD) have space limitations between the bottom of the PCB and the floor of the bottom connector backshell. This space limitation typically dictates that three of the incoming four cables are attached to the upper side of the PCB, and the fourth cable is attached on the bottom or lower side of the PCB. Placing three rows on the upper side requires a longer PCB with longer circuit traces, which contributes to the total insertion loss of the system. Moving the third cable and associated solder pads from the upper side of the PCB to the lower side of the PCB, near the edge of the PCB, may shorten the circuit traces required and reduce insertion loss. For example, such as in the case of standard OSFP and QSFP-DD form factor connectors, PCB traces may be shortened by 10 mm or more, resulting in an insertion loss improvement of approximately 0.3 dB.

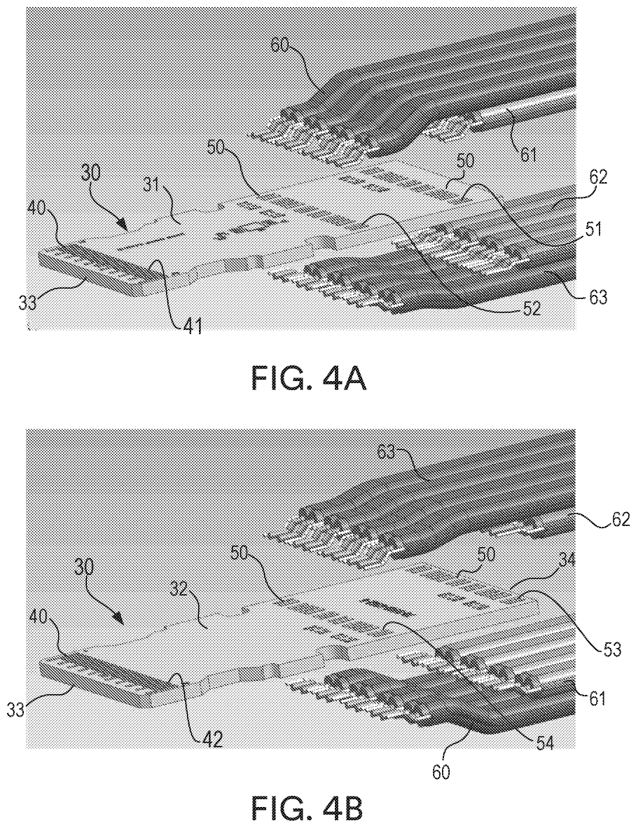

It should be noted that, although many of the examples and figures provided herein describe the use of four cables, these examples are not intended to be limiting. Typically, a cable is defined as a set of two or more electrical conductors presented in a single bundle or package (e.g., two or more conductors in a shared sleeve of insulating material). The example embodiments described herein with four cables (e.g., cables 60, 61, 62, and 63 of FIG. 4A) could be done with any appropriate number of cables. For example, cable 60 of FIG. 4A (shown in the figure as having 16 conductors) could be replaced with two smaller cables with eight connectors each, four smaller cables with four conductors each, eight smaller cables with two conductors each, one cable with 12 conductors and one cable with four conductors, or any other appropriate combination of smaller cables and conductors. It should also be noted that one or more of the “cables” depicted in the examples and figures herein could be replaced with individual insulated conductors without deviating from the intent of the concepts described herein. For the purposes of this specification, the term “cable” shall be defined to include any appropriate combination of smaller cables and/or individual conductors

According to some aspects of the present description, a connector assembly is provided, including a housing, a printed circuit board (also “circuit board” or “PCB”), and a plurality of cables, each including a plurality of conductors. In some embodiments, the housing includes top and bottom housing portions assembled to each other and defining a housing cavity therebetween. The housing includes a mating end for mating with a mating connector and an opposing cable end for receiving one or more cables.

In some embodiments, the circuit board is disposed in the housing cavity and includes an upper major surface, an opposing lower major surface, a front edge near the mating end, and a rear edge opposite the front edge and near the cable end. In some embodiments, the circuit board includes a plurality of conductive front pads disposed on the upper and lower major surfaces near the front edge (e.g., conductive pads corresponding to mating connection points in a mating connector assembly), and a plurality of conductive rear pads disposed on the upper and lower major surfaces near the rear edge and electrically connected to the front pads. In some embodiments, the front pads form a first row of front pads disposed on the upper major surface of the circuit board, and a second row of front pads disposed on the lower surface of the circuit board.

In some embodiments, the rear pads form first and second rows of rear pads on each of the upper and lower major surfaces, with the first row disposed near the rear edge and the second row disposed between the first row and the front pads. In other words, each of the upper and lower major surfaces of the circuit board include two rows of rear pads: a first row of rear pads proximate the rear edge of the circuit board, and a second row of rear pads farther away from the rear edge.

In some embodiments, the cable end of the housing receives and connects to a plurality of incoming cables (e.g., four incoming cables). In some embodiments, at least one of the plurality of cables may be substantially flat (i.e., the thickness or height of the cable is relatively small compared with the width and/or the length of the cable). The plurality of conductors of the cables include uninsulated front ends terminated at the rear pads of the first and second rows of the rear pads on the upper and lower major surfaces. In some embodiments, for one of the first rows, at least a portion of each uninsulated front end is disposed between upper and lower planes defined by the respective upper and lower major surfaces (i.e., by connecting to rear pads located near the rear edge of the circuit board, the bulk of the insulated portion of the cables can be positioned behind the edge of and substantially in-plane with the circuit board, rather than above or below the circuit board).

In some embodiments, the connector assembly may be an Octal Small Form Factor Pluggable Module (OSFP) connector assembly. In other embodiments, the connector assembly may be a Quad Small Form Factor Pluggable Double Density (QSFP-DD) small form factor.

According to some aspects of the present description, a connector assembly is provided, including a housing, a printed circuit board (“circuit board” or “PCB”), and at least one cable. In some embodiments, the circuit board is at least partially disposed inside the housing and includes a plurality of conductive pads disposed on a first major surface thereof, opposite a second major surface. The cable includes a plurality of conductors. In some embodiments, the uninsulated front ends of the conductors are terminated at the conductive pads on the circuit board, such that at least a portion of each uninsulated front end is disposed between first and second planes defined by the first and second major surfaces. In some embodiments, the conductive pads may be disposed near an edge of the circuit board, such that the bulk of the insulated portion of the cables can be positioned behind the edge of and substantially in-plane with the circuit board when the uninsulated front ends are terminated at the conductive pads.

In some embodiments, the cable may be substantially flat. In some embodiments, the cable may include a plurality of insulated conductors and a plurality of uninsulated conductors. For example, the uninsulated conductors may include uninsulated drain conductors.

In some embodiments, the housing may include a top housing portion and a bottom housing portion, the top and bottom housing portions assembled to each other and defining a housing cavity therebetween. In some embodiments, the circuit board may be disposed within the housing cavity. In some embodiments, the housing may be metal. In some embodiments, the connector assembly may further include a pull tab or a push-pull tab assembled to the housing (e.g., an extended tab of material for mating and/or de-mating a connector in a highly-congested application).

According to some aspects of the present description, a circuit board assembly is provided, including a circuit board including opposing first and second major surfaces. In some embodiments, uninsulated portions of first and second insulated conductors are terminated at conductive pads disposed on the respective first and second major surfaces, such that, in a side plan view, the uninsulated portion of only one of the first and second conductors extends beyond an edge of the circuit board. In some embodiments, the uninsulated portion of the conductors that extends beyond the edge of the circuit board may be disposed between upper and lower planes defined by the first and second major surfaces of the circuit board.

In some embodiments, the uninsulated portions of the first and second insulated conductors may be soldered to the conductive pads on the first and second major surfaces of the circuit board. In some embodiments, the conductors of the insulated conductors may have diameters not greater than 22 American Wire Gauge (AWG).

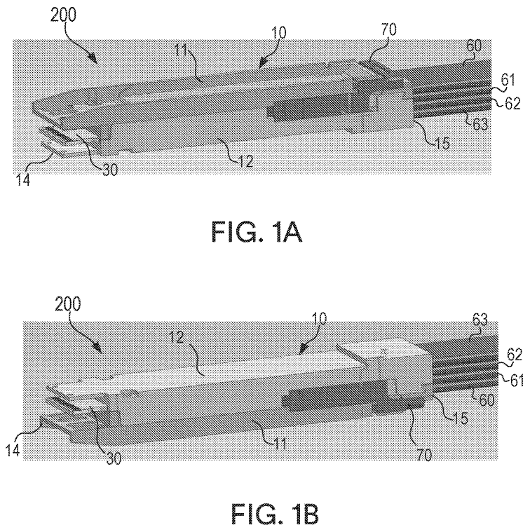

Turning now to the figures, FIGS. 1A and 1B are perspective views of a connector assembly, in accordance with an embodiment described herein. FIG. 1A provides a top perspective view of connector assembly 200, and FIG. 1B provides a bottom perspective view of connector assembly 200. FIGS. 1A and 1B should be viewed together for the following description.

A connector assembly 200 includes a housing 10, including a mating end 14 and a cable end 15. In some embodiments, the housing 10 includes a top housing 11 and a bottom housing 12, which are assembled together to form housing 10 and to define a housing cavity (not shown in FIGS. 1A/1B, but discussed in additional figures herein). In some embodiments, a printed circuit board (PCB) 30 is disposed within the housing cavity.

Conductors from one or more cables enter the cable end 15 of housing 10 and are terminated at conductive pads on PCB 30 (not shown). In some embodiments, four cables 60, 61, 62, and 63 are terminated at PCB 30. For example, a connector assembly 200 designed to standards such as OSFP or QSFP-DD, may have four cables 60-63 as shown in FIGS. 1A and 1B. In a typical connector assembly of the prior art, three of these cables 60, 61, and 62 would be terminated on an upper major surface of the PCB 30, and one cable 63 would be terminated on a lower major surface of PCB 30. However, in accordance with an embodiment described herein, cable 62 may be moved from an upper major surface of PCB 30 to a lower major surface of PCB 30 (i.e., cables 60 and 61 would be terminated on the upper major surface and cables 62 and 63 would be terminated on the lower major surface.)

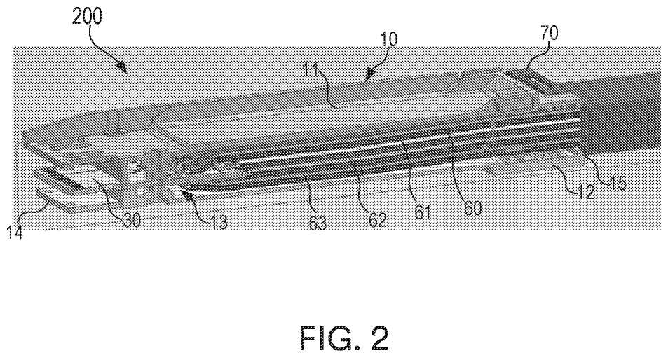

FIG. 2 is a perspective, cutaway view of the connector assembly 200 of FIGS. 1A-1B, detailing the termination of cables 60-63. In FIG. 2, connector housing 10 is cut down one side, revealing the details of housing cavity 13. PCB 30 is shown extending from the mating end 14 of housing cavity 10, held in place between top housing 11 and bottom housing 12. PCB 30 extends partially back into housing cavity 13, where it meets and connects to cables 60 and 61 on an upper major surface, and cables 62 and 63 on a lower major surface. Cables 60-63 enter connector housing 10 via a cable end 15. In some embodiments, and as shown in FIG. 2, at least one cable (cable 62 in this embodiment) is terminated near a rear edge of PCB 30 and at least a portion of each conductor of cable 62 (including at least a portion of an uninsulated front portion of each conductor) is disposed between upper and lower planes defined by the respective upper and lower major surfaces of PCB 30 (i.e., by connecting to rear pads located near the rear edge of the circuit board, the bulk of at least portions of cable 62 can be positioned behind the edge of and substantially in-plane with the circuit board, rather than above or below the circuit board, as cables 60, 61, and 63, as shown in FIG. 2).

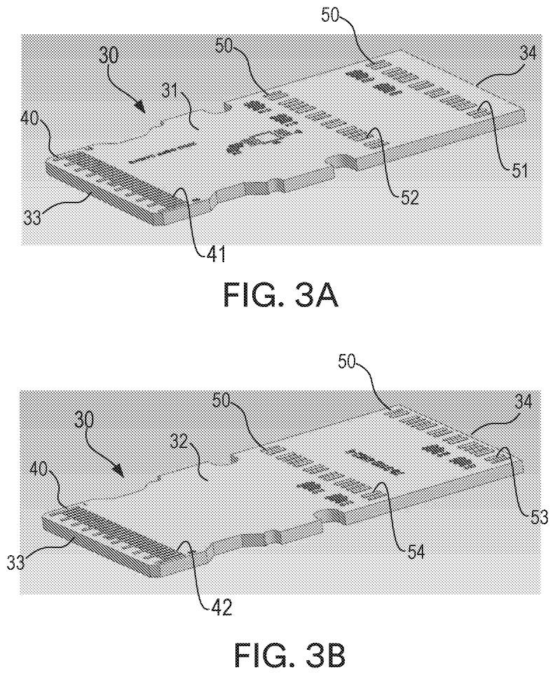

FIGS. 3A and 3B are perspective views of an embodiment of a PCB for a connector assembly, such as PCB 30 of FIGS. 1A, 1B, and 2. FIGS. 4A and 4B are exploded views of an embodiment of a PCB and corresponding cables, detailing how the cables may be terminated on the PCB. FIGS. 3A and 4A provide top perspective views. FIGS. 3B and 4B provide bottom perspective views. All four figures should be examined for the following description.

A PCB 30 includes an upper major surface 31 and a lower major surface 32. PCB 30 also includes a front edge 33 proximate the mating end 14 (mating end 14 of connector assembly 200, see at least FIG. 1A) and a rear edge 34 opposite the front edge and proximate the cable end 15 of connector assembly 200 (see at least FIG. 1A). PCB 30 includes a plurality of conductive front pads 40 disposed on the upper major surface 31 and the lower major surface 32. In some embodiments, conductive front pads 40 may form a first row 41 disposed on upper major surface 31 and second row 42 disposed on lower major surface 32 (i.e., front pads 40 may be divided into first row 41 and second row 42, each disposed on opposite sides of PCB 30).

In some embodiments, PCB 30 may further include a plurality of conductive rear pads 50 disposed on the upper major surface 31 and the lower major surface 32. Rear pads 50 may form first row of rear pads 51 and second row of rear pads 52 on the upper major surface 31, and first row of rear pads 53 and second row or rear pads 54 on the lower major surface 32.

In some embodiments, first row of rear pads 51 may be disposed on upper major surface 31 proximate the rear edge 34 of PCB 30, and first row of rear pads 53 may be disposed on lower major surface 32 proximate the rear edge 34 of PCB 30. In some embodiments, second row of rear pads 52 may be disposed on the upper major surface 31 between first row of rear pads 51 and first row of front pads 41, and second row of rear pads 54 may be disposed on lower major surface 32 between first row of rear pads 53 and second row of front pads 42.

FIG. 4A provides a top perspective view of PCB 30, detailing how, in some embodiments, cables 60 and 61 are terminated on the upper major surface 31 of PCB 30, and cables 62 and 63 are terminated on the lower major surface 32. FIG. 4B shows a bottom perspective view of the same assembly. It should be noted that, for clarity, the exploded views of FIGS. 4A and 4B show the conductors of cables 60-63 just above rather than terminated on corresponding sets of conductive pads. In some embodiments, uninsulated portions of the conductors of cable 60 may be terminated at second row of rear pads 52 on upper major surface 31 of PCB 30. In some embodiments, uninsulated portions of the conductors of cable 61 may be terminated at first row of rear pads 51 on upper major surface 31 of PCB 30. In some embodiments, uninsulated portions of the conductors of cable 62 may be terminated at second row of rear pads 54 on lower major surface 32 of PCB 30. In some embodiments, uninsulated portions of the conductors of cable 63 may be terminated at first row of rear pads 53 on lower major surface 32 of PCB 30.

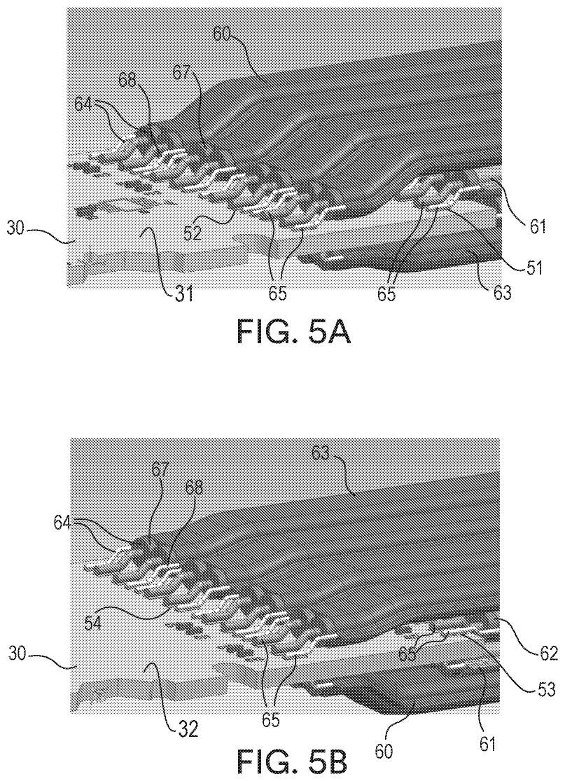

FIGS. 5A and 5B are perspective views of the cable terminations on the PCB, and show additional detail regarding the terminations. FIG. 5A provides a top perspective view, and FIG. 5B provides a bottom perspective view. In the embodiments of FIGS. 5A and 5B, four cables 60-63 are shown terminated at corresponding sets of conductive pads on PCB 30. Each of cables 60, 61, 62, and 63 include a plurality of conductors 64. In some embodiments, conductors 64 may include insulated conductors 67 and uninsulated conductors 68 (e.g., uninsulated drain wires). In some embodiments, each conductor 64 includes an uninsulated front end 65 which is terminated at a corresponding conductive pad on PCB 30. For example, as in the embodiment of FIG. 5A, uninsulated front ends 65 of conductors 64 of cable 60 may be terminated at second row of rear pads 52 on upper major surface 31. In some embodiments, uninsulated front ends 65 of conductors 64 of cable 61 may be terminated at first row of rear pads 51 on upper major surface 31.

In the embodiment shown in FIG. 5B, uninsulated front ends 65 of conductors 64 of cable 62 may be terminated at first row of rear pads 53 on lower major surface 32. In some embodiments, uninsulated front ends 65 of conductors 64 of cable 63 may be terminated at second row of rear pads 54 on lower major surface 32.

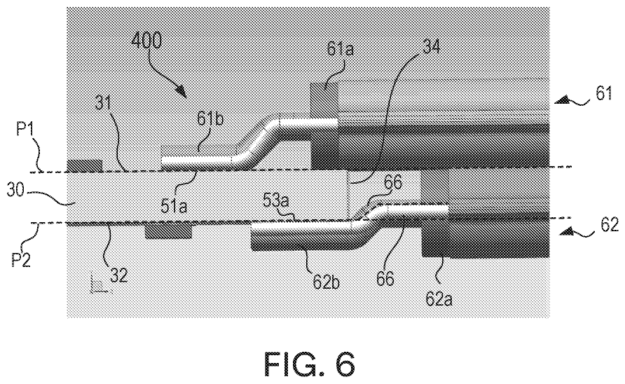

Finally, FIG. 6 provides a side view of cable terminations for a circuit board assembly in accordance with an embodiment disclosed herein. FIG. 6 shows a circuit board assembly 400 which includes terminations with two cables 61 and 62. For simplicity, only cables 61 and 62 are shown in FIG. 6, to focus on the terminations between these two inner cables proximate the rear edge 34 of PCB 30, and specifically on the terminations of a first insulated conductor 61a of cable 61 and a second insulated conductor 62a of cable 62. First insulated conductor 61a has an uninsulated portion 61b which is terminated on the PCB 30 at conductive pad 51a. Second insulated conductor 62a has an uninsulated portion 62b which is terminated on the PCB 30 at conductive pad 53a. It should be noted that uninsulated portion 62b extends beyond rear edge 34 of PCB 30, such that at least a portion 66 of uninsulated portion 62b (as well as each of the uninsulated front ends of the conductors of cable 62) is disposed between planes P1 and P2 defined by the first (upper) major surface 31 and second (lower) major surface 32. By terminating cable 62 in such a manner, near a rear edge 34 of PCB 30, such that the uninsulated front end (uninsulated portion) 62b extends beyond rear edge 34, at least a portion of the bulk of cable 62 can rest behind and in-plane with PCB 30, rather than being disposed either above or beneath PCB 30, where it consumes valuable volume.

Terms such as “about” will be understood in the context in which they are used and described in the present description by one of ordinary skill in the art. If the use of “about” as applied to quantities expressing feature sizes, amounts, and physical properties is not otherwise clear to one of ordinary skill in the art in the context in which it is used and described in the present description, “about” will be understood to mean within 10 percent of the specified value. A quantity given as about a specified value can be precisely the specified value. For example, if it is not otherwise clear to one of ordinary skill in the art in the context in which it is used and described in the present description, a quantity having a value of about 1, means that the quantity has a value between 0.9 and 1.1, and that the value could be 1.

Terms such as “substantially” will be understood in the context in which they are used and described in the present description by one of ordinary skill in the art. If the use of “substantially equal” is not otherwise clear to one of ordinary skill in the art in the context in which it is used and described in the present description, “substantially equal” will mean about equal where about is as described above. If the use of “substantially parallel” is not otherwise clear to one of ordinary skill in the art in the context in which it is used and described in the present description, “substantially parallel” will mean within 30 degrees of parallel. Directions or surfaces described as substantially parallel to one another may, in some embodiments, be within 20 degrees, or within 10 degrees of parallel, or may be parallel or nominally parallel. If the use of “substantially aligned” is not otherwise clear to one of ordinary skill in the art in the context in which it is used and described in the present description, “substantially aligned” will mean aligned to within 20% of a width of the objects being aligned. Objects described as substantially aligned may, in some embodiments, be aligned to within 10% or to within 5% of a width of the objects being aligned.

All references, patents, and patent applications referenced in the foregoing are hereby incorporated herein by reference in their entirety in a consistent manner. In the event of inconsistencies or contradictions between portions of the incorporated references and this application, the information in the preceding description shall control.

Descriptions for elements in figures should be understood to apply equally to corresponding elements in other figures, unless indicated otherwise. Although specific embodiments have been illustrated and described herein, it will be appreciated by those of ordinary skill in the art that a variety of alternate and/or equivalent implementations can be substituted for the specific embodiments shown and described without departing from the scope of the present disclosure. This application is intended to cover any adaptations or variations of the specific embodiments discussed herein. Therefore, it is intended that this disclosure be limited only by the claims and the equivalents thereof.

What is claimed is:

1. A connector assembly comprising:
a housing comprising top and bottom housing portions assembled to each other and defining a housing cavity therebetween, the housing comprising a mating end for mating with a mating connector and an opposing cable end for receiving one or more cables;
a circuit board disposed in the housing cavity and comprising:
an upper major surface and an opposing lower major surface;
a front edge proximate the mating end and a rear edge opposite the front edge and proximate the cable end;
a plurality of conductive front pads disposed on the upper and lower major surfaces proximate the front edge; and
a plurality of conductive rear pads disposed on the upper and lower major surfaces proximate the rear edge and electrically connected to the front pads, the rear pads forming first and second rows of rear pads on each of the upper and lower major surfaces with the first row disposed proximate the rear edge and the second row disposed between the first row and the front pads; and
a plurality of cables comprising a plurality of conductors, uninsulated front ends of the conductors of the plurality of cables terminated at the rear pads of the first and second rows of the rear pads on the upper and lower major surfaces, wherein for one of the first rows, at least a portion of each uninsulated front end is disposed between upper and lower planes defined by the respective upper and lower major surfaces.

2. The connector assembly of claim 1 being an octal small form factor pluggable (OSFP) connector assembly.

3. The connector assembly of claim 1 being a quad small form factor pluggable double density (QSFP-DD) connector assembly.

4. The connector assembly of claim 1, wherein the front pads form a first row of front pads disposed on the upper surface and a second row of front pads disposed on the lower surface.

5. The connector assembly of claim 1, wherein at least one of the plurality of cables is substantially flat.

6. The connector assembly of claim 1, wherein the plurality of cables comprises four cables.

7. A connector assembly comprising:
a housing;
a circuit board at least partially disposed inside the housing and comprising a plurality of conductive pads disposed on a first major surface thereof opposite a second major surface; and
a cable comprising a plurality of conductors, uninsulated front ends of the conductors terminated at the conductive pads, at least a portion of each uninsulated front end disposed between first and second planes defined by the first and second major surfaces.

8. The connector assembly of claim 7, wherein the housing comprises top and bottom housing portions assembled to each other and defining a housing cavity therebetween, and wherein the circuit board is disposed in the housing cavity.

9. The connector assembly of claim 7, wherein the cable is substantially flat.

10. The connector assembly of claim 7, wherein the cable comprises a plurality of insulated conductors and a plurality of uninsulated drain conductors.

11. The connector assembly of claim 7 further comprising a pull tab assembled to the housing.

12. The connector assembly of claim 7, wherein the housing is made of a metal.

13. A circuit board assembly comprising:
a circuit board comprising opposing first and second major surfaces;
uninsulated portions of first and second insulated conductors terminated at conductive pads disposed on the respective first and second major surfaces, wherein in a side plan view, the uninsulated portion of only one of the first and second conductors extends beyond an edge of the circuit board.

14. The circuit board assembly of claim 13, wherein the conductors of the insulated conductors have diameters not greater than 22 American Wire Gauge (AWG).

15. The circuit board assembly of claim 13, wherein the uninsulated portion of the conductors that extends beyond the edge of the circuit board is disposed between upper and lower planes defined by the first and second major surfaces.

16. The circuit board assembly of claim 13, wherein the uninsulated portions of the first and second insulated conductors are soldered to the conductive pads.
